(19) United States
(12) Patent Application Publication
(10) Pub. No.: US 2025/0241214 A1
(43) Pub. Date: Jul. 24, 2025

(54) SEMICONDUCTOR DEVICE

(71) Applicant: SK hynix Inc., Icheon-si (KR)

(72) Inventors: Yong Hun SUNG, Icheon-si (KR); Jun Ku AHN, Icheon-si (KR)

(21) Appl. No.: 18/952,769

(22) Filed: Nov. 19, 2024

(30) Foreign Application Priority Data
Jan. 19, 2024 (KR) 10-2024-0008718

(51) Int. Cl. H10N 70/00; H10B 63/00; H10N 70/20

(52) U.S. Cl. CPC H10N 70/8845; H10B 63/20; H10N 70/063; H10N 70/24; H10N 70/841; H10N 70/8833

(57) ABSTRACT

A semiconductor device includes at least one memory cell. The memory cell includes a first electrode layer, a second electrode layer spaced apart from the first electrode layer, and a memory layer interposed between the first electrode layer and the second electrode layer. The first electrode layer includes a first amorphous carbon layer and a first graphene-containing layer interposed between the memory layer and the first amorphous carbon layer.

### CROSS-REFERENCE TO RELATED APPLICATION

The present application claims priority under 35 U.S.C 119 (a) to Korean Patent Application No. 10-2024-0008718, filed on Jan. 19, 2024, in the Korean Intellectual Property Office, which is incorporated herein by reference in its entirety.

### BACKGROUND

### 1. Field

Embodiments of the present disclosure relate to a semiconductor technology, and more particularly, to a semiconductor device including a memory cell having a graphene-containing layer, and a method for fabricating the semiconductor device.

### 2. Description of the Related Art

Recent trends for miniaturization, low-power consumption, high performance, and diversification of electronic devices require semiconductor devices that may store data in diverse electronic devices, such as computers and portable communication devices, and researchers and the industry are studying to develop such semiconductor devices. Such semiconductor devices include semiconductor devices that may store data by using the characteristics of switching between different resistance states according to the applied voltage or current, for example, a Resistive Random Access Memory (RRAM), a Phase-change Random Access Memory (PRAM), a Ferroelectric Random Access Memory (FRAM), a Magnetic Random Access Memory (MRAM), an E-fuse, and the like.

### SUMMARY

Embodiments of the present disclosure are directed to a semiconductor device that may improve the characteristics of memory cells, and a method for fabricating the semiconductor device.

In accordance with an embodiment of the present disclosure, a semiconductor device includes at least one memory cell. The memory cell includes a first electrode layer, a second electrode layer spaced apart from the first electrode layer, and a memory layer interposed between the first electrode layer and the second electrode layer. The first electrode layer includes a first amorphous carbon layer and a first graphene-containing layer interposed between the memory layer and the first amorphous carbon layer.

In accordance with another embodiment of the present disclosure, a semiconductor device includes at least one memory cell. The memory cell includes a first electrode layer including a first amorphous carbon layer, a memory layer disposed over the first electrode layer, and a second electrode layer disposed over the memory layer and including a second amorphous carbon layer and a graphene-containing layer interposed between the second amorphous carbon layer and the memory layer. A top surface of the first amorphous carbon layer directly contacts the memory layer.

### BRIEF DESCRIPTION OF THE DRAWINGS

FIG. 1 is a perspective view illustrating a semiconductor device in accordance with an embodiment of the present disclosure.

FIG. 2 is a cross-sectional view taken along a line A-A′ and a line B-B′ shown in FIG. 1.

FIG. 3 is a cross-sectional view illustrating a semiconductor device in accordance with another embodiment of the present disclosure.

FIG. 4 is a cross-sectional view illustrating a semiconductor device in accordance with another embodiment of the present disclosure.

FIG. 5 is a cross-sectional view illustrating a semiconductor device in accordance with another embodiment of the present disclosure.

FIG. 6 is a cross-sectional view illustrating a semiconductor device in accordance with another embodiment of the present disclosure.

FIG. 7 is a cross-sectional view illustrating a semiconductor device in accordance with another embodiment of the present disclosure.

FIG. 8 is a cross-sectional view illustrating a semiconductor device in accordance with another embodiment of the present disclosure.

### DETAILED DESCRIPTION

Hereinafter, various embodiments of the present disclosure will be described in detail with reference to the attached drawings.

Some embodiments of the present disclosure will be described below in more detail with reference to the accompanying drawings. Various embodiments of the present disclosure may, however, be embodied in different forms and should not be construed as limited to the embodiments set forth herein. Rather, these embodiments are provided so that this disclosure will be thorough and complete, and will fully convey the scope of embodiments of the present disclosure to those skilled in the art. Throughout the disclosure, like reference numerals refer to like parts throughout the various figures and embodiments of the present disclosure.

The drawings are not necessarily to scale and in some instances, proportions may have been exaggerated in order to clearly illustrate features of the embodiments. When a first layer is referred to as being ‘on’ a second layer or ‘on’ a substrate, it not only refers to a case where the first layer is formed directly on the second layer or the substrate, but also a case where one or more intermediate layers exist between the first layer and the second layer or the substrate. As used herein, including in the claims, “or” as used in a list of items (e.g., a list of items prefaced by a phrase such as “at least one of” or “one or more of” or “one or both of”) indicates an inclusive list such that, for example, a list of at least one of A, B, or C indicates A or B or C or AB or AC or BC or ABC (i.e., A and B and C).

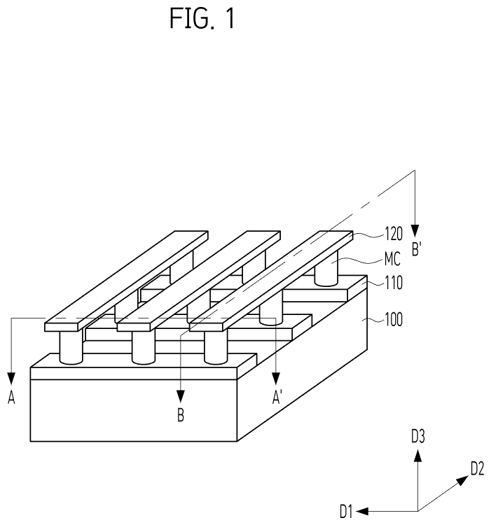

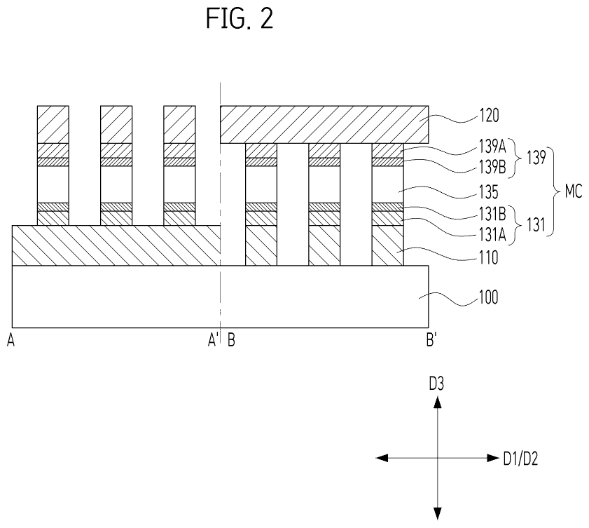

FIG. 1 is a perspective view illustrating a semiconductor device in accordance with an embodiment of the present disclosure. FIG. 2 is a cross-sectional view taken along a line A-A′ and a line B-B′ shown in FIG. 1.

Referring to FIGS. 1 and 2, the semiconductor device in accordance with this embodiment of the present disclosure may include a substrate 100, a plurality of first conductive lines 110 formed over the substrate 100 and extending in a first direction D1, a plurality of second conductive lines 120 formed over the first conductive lines 110 to be spaced apart from the first conductive lines 110 and to extend in a second direction D2 intersecting with the first direction D1, and memory cells MC disposed between the first conductive lines 110 and the second conductive lines 120 to respectively overlap at the intersection areas between the first conductive lines 110 and the second conductive lines 120. Here, the first direction D1 and the second direction D2 each may correspond to a horizontal direction which is substantially parallel to the top surface of the substrate 100. The direction substantially perpendicular to the top surface of the substrate 100 will be, hereinafter, referred to as a third direction D3.

The substrate 100 may include a semiconductor material, such as silicon. The substrate 100 may include a given lower structure (not shown) formed therein. For example, the substrate 100 may include a driving circuit (not shown) that is electrically connected to the first conductive line 110 and/or the second conductive line 120 and controls them.

Each of the first conductive lines 110 and the second conductive lines 120 may include one or more conductive materials, for example, a metal such as platinum (Pt), tungsten (W), aluminum (Al), copper (Cu), tantalum (Ta) and the like, a metal nitride, such as titanium nitride (TiN), tantalum nitride (TaN) and the like, or a combination thereof. The first conductive line 110 and the second conductive line 120 may be coupled to the bottom and top portions of the memory cell MC, respectively, and transfer a voltage or current to the memory cell MC, thereby enabling an operation of the memory cell MC. For example, a write operation for storing data in the memory cell MC, a read operation for reading the data stored in the memory cell MC, and the like may be performed. When the first conductive line 110 functions as a word line, the second conductive line 120 may function as a bit line. Conversely, when the first conductive line 110 functions as a bit line, the second conductive line 120 may function as a word line.

The memory cell MC may be a device that stores different data according to the voltage or current applied through the first conductive line 110 and the second conductive line 120. The memory cell MC may have a pillar shape that overlaps at the intersection between the first conductive line 110 and the second conductive line 120. Although it is illustrated in FIG. 1 that the memory cell MC has a cylindrical shape, embodiments of the present disclosure are not limited thereto. The shape of the memory cell MC may be diversely modified into a square pillar, an elliptical pillar, and the like.

According to this embodiment of FIG. 2, the memory cell MC may include a memory layer 135 that performs a function of storing data, a first electrode layer 131 interposed between the memory layer 135 and the first conductive line 110, and a second electrode layer 139 interposed between the memory layer 135 and the second conductive line 120. The first electrode layer 131 may include a first amorphous carbon layer 131A, and a first graphene-containing layer 131B interposed between the memory layer 135 and the first amorphous carbon layer 131A. The second electrode layer 139 may include a second amorphous carbon layer 139A, and a second graphene-containing layer 139B interposed between the memory layer 135 and the second amorphous carbon layer 139A.

The memory layer 135 may store data in diverse ways. For example, the memory layer 135 may store different data by having variable resistance characteristics, that is, the characteristics of switching between different resistance states according to the applied voltage or current. This memory layer 135 may have a single-layer structure or a multi-layer structure including diverse materials used in a Resistive Random Access Memory (RRAM), a Phase-change Random Access Memory (PRAM), a Ferroelectric Random Access Memory (FRAM), a Magnetic Random Access Memory (MRAM), and the like, for example, metal oxides such as transition metal oxides, perovskite-based materials and the like, phase-change materials such as chalcogenide-based materials, ferroelectric materials, ferromagnetic materials, and the like.

Also, the memory layer 135 may have the characteristics as a selector of being turned on or off based on a predetermined threshold voltage as well as the variable resistance characteristics of switching between different resistance states according to the applied voltage or current. This memory layer 135 may be referred to as a self-selecting memory layer. Since the self-selecting memory layer has different threshold voltages in the different resistance states, the function as a memory and the function as a selector may be realized simultaneously. This memory layer 135 may include, for example, a chalcogenide-based material, and may perform switching between a high-resistance state and a low-resistance state according to the migration of a predetermined chalcogen element in the chalcogenide-based material. Herein, the threshold voltage in the high-resistance state and the threshold voltage in the low-resistance state may be different from each other.

The first electrode layer 131 may be interposed between the first conductive line 110 and the memory layer 135 and may function to electrically connect them to each other while physically separating them from each other. The first electrode layer 131 may include a first amorphous carbon layer 131A. When a conventional metal-containing material is used as the first electrode layer 131, the metal of the metal-containing material may be diffused into the memory layer 135 during the operation of the memory cell MC, negatively affecting the characteristics of the memory layer 135. In contrast, when the first amorphous carbon layer 131A is used as the first electrode layer 131, the metal diffusion into the memory layer 135 may be fundamentally prevented. However, when the first electrode layer 131 includes only the first amorphous carbon layer 131A, a specific constituent element among the constituent elements of the memory layer 135 may be diffused into the first amorphous carbon layer 131A during the operation of the memory cell MC. In particular, when the memory layer 135 includes a chalcogenide-based material, such as a self-selecting memory layer, a specific chalcogen element of the chalcogenide-based material, such as selenium, may be diffused into the first amorphous carbon layer 131A. In this case, since the specific constituent element of the memory layer 135 may be lost and thus the composition of the memory layer 135 may be changed, deteriorated characteristics of the memory layer 135 may occur. To address this issue, according to an embodiment of the present disclosure, the first graphene-containing layer 131B may be used. In other words, the first electrode layer 131 includes the first amorphous carbon layer 131A to preclude diffusion of a metal from a conventional metal-containing electrode into the memory layer 135. The first electrode layer 131 further includes the first graphene-containing layer 131B to substantially block diffusion of one more elements of the memory layer 135 into the first amorphous carbon layer 131A, as will be described below in more detail.

The first graphene-containing layer 131B may be interposed between the memory layer 135 and the first amorphous carbon layer 131A and may function to electrically connect them to each other while physically separating them from each other. The first graphene-containing layer 131B may include a single layer of graphene or graphite in which graphene is stacked in multiple layers. Since the first graphene-containing layer 131B has a two-dimensional planar crystal structure, it may effectively block the migration of an element in a direction perpendicular to the crystal plane, for example, in the third direction D3. Accordingly, the first graphene-containing layer 131B may serve to prevent and/or reduce diffusion of the specific constituent element of the memory layer 135 into the first amorphous carbon layer 131A during the operation of the memory cell MC. In other words, the first graphene-containing layer 131B may function as a diffusion barrier in an out-of-plane direction (e.g., the third direction D3) perpendicular to an in-plane direction thereof. In particular, when the memory layer 135 includes a chalcogenide-based material like a self-selecting memory layer, it may prevent and/or reduce a predetermined chalcogen element of the chalcogenide-based material, such as selenium, from being diffused into the first amorphous carbon layer 131A. Also, since the first graphene-containing layer 131B has a two-dimensional planar crystal structure, it may prevent and/or reduce heat generated during the operation of the memory cell MC from being transferred to the outside in a direction perpendicular to the crystal plane, for example, in the third direction D3. In this case, the operation power of the memory cell MC may be reduced due to the thermal insulation effect on the memory cell MC. In other words, the first graphene-containing layer 131B has a relatively lower thermal conductivity in an out-of-plane direction (e.g., the third direction D3) to increase a thermal resistance in the out-of-plane direction. As a result, the first graphene-containing layer 131B functions as a thermal insulator that significantly reduces an amount of heat transferred from a memory cell MC to outside thereof in the out-of-plane direction during an operation of the memory cell MC. Therefore, power required for the operation of the memory cell MC may be reduced using the first electrode layer 131 including the first graphene-containing layer 131B according to an embodiment of the present disclosure.

When the first electrode layer 131 includes a stacked structure of the first amorphous carbon layer 131A and the first graphene-containing layer 131B, it may be easy to obtain the characteristics required by the first electrode layer 131, such as desired electrical conductivity and thermal conductivity. The thermal conductivity and the electrical conductivity of the first graphene-containing layer 131B may be lower than those of the first amorphous carbon layer 131A. Specifically, the thermal conductivity and the electrical conductivity of the first graphene-containing layer 131B in the out-of-plane direction (or the out-of-plane thermal conductivity and out-of-plane electrical conductivity) may be lower than thermal conductivity and the electrical conductivity of the first amorphous carbon layer 131A, respectively. Accordingly, at least one of the electrical conductance or the thermal conductance of the first electrode layer 131 may be adjusted by controlling the thickness of the first amorphous carbon layer 131A and the thickness of the first graphene-containing layer 131B. Specifically, the thickness of the first amorphous carbon layer 131A and the thickness of the first graphene-containing layer 131B each may be a length in direction corresponding to the out-of-plane direction of the first graphene-containing layer 131B (e.g., the third direction D3). For example, when it is determined that the electrical conductance of the first electrode layer 131 (e.g., the electrical conductance in the third direction D3) is lower than a target level, the electrical conductance of the first electrode layer 131 may be increased by increasing the thickness of the first amorphous carbon layer 131A more than the thickness of the first graphene-containing layer 131B. In other words, the first amorphous carbon layer 131A may be used as the first electrode layer 131 together with the first graphene-containing layer 131B to compensate for the low electrical conductance of the first graphene-containing layer 131B. For example, when it is determined that the thermal conductance of the first electrode layer 131 is higher than a target level and thus the operation power is increased, the thickness of the first graphene-containing layer 131B may be increased more than the thickness of the first amorphous carbon layer 131A to reduce the thermal conductance of the first electrode layer 131. In some embodiments, the thickness of the first graphene-containing layer 131B may be about 30% to about 70% of a total thickness of the first electrode layer 131. When the thickness of the first graphene-containing layer 131B is less than about 30% of the total thickness of the first electrode layer 131, the first graphene-containing layer 131B may not properly function as a thermal insulator to sufficiently reduce power required for the operation of the memory cell MC, or a diffusion barrier to effectively block diffusion of one or more elements of the memory layer 135 into the first amorphous carbon layer 131A, or both. When the thickness of the first graphene-containing layer 131B is greater than about 70% of the total thickness of the first electrode layer 131, the first amorphous carbon layer 131A may not sufficiently compensate for the low electrical conductance of the first graphene-containing layer 131B.

The second electrode layer 139 may be interposed between the second conductive line 120 and the memory layer 135 to electrically connect them to each other while physically separating them from each other. The second electrode layer 139 may include the second amorphous carbon layer 139A and the second graphene-containing layer 139B. When the second amorphous carbon layer 139A is used as the second electrode layer 139, the metal diffusion into the memory layer 135 may be fundamentally blocked off. The second graphene-containing layer 139B may be interposed between the memory layer 135 and the second amorphous carbon layer 139A to electrically connect them to each other while physically separating them from each other. The second graphene-containing layer 139B may include a single layer of graphene or graphite in which graphene is stacked in multiple layers. The second graphene-containing layer 139B may serve to prevent and/or reduce the diffusion and loss of a specific constituent element of the memory layer 135 into the second amorphous carbon layer 139A during the operation of the memory cell MC. Also, the second graphene-containing layer 139B may block and/or reduce the heat generated during the operation of the memory cell MC from being transferred to the outside.

When the second electrode layer 139 includes a stacked structure of the second amorphous carbon layer 139A and the second graphene-containing layer 139B, the electrical conductivity and the thermal conductivity of the second electrode layer 139 may be adjusted by adjusting the relative thicknesses of the second amorphous carbon layer 139A and the second graphene-containing layer 139B.

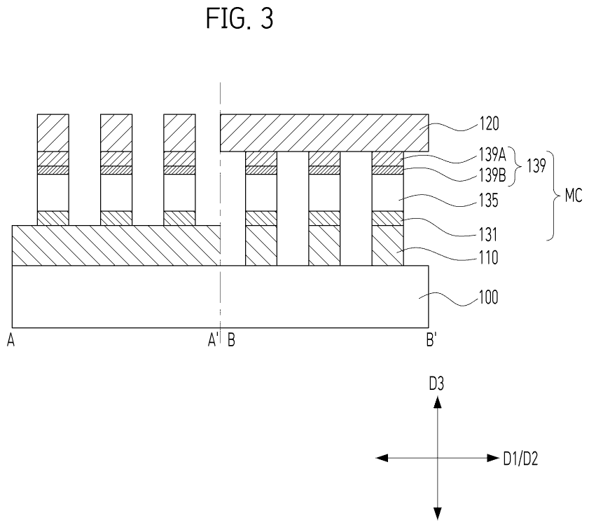

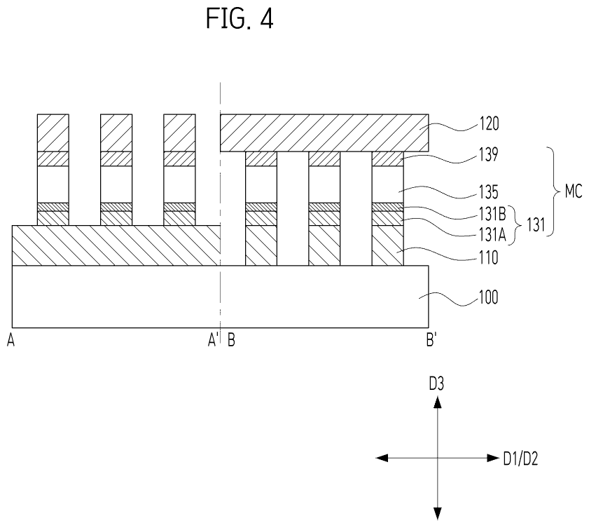

According to this embodiment of the present disclosure, the first electrode layer 131 and the second electrode layer 139 may be substantially symmetrical to each other with respect to the memory layer 135 interposed therebetween. Accordingly, the thickness of the first amorphous carbon layer 131A and the thickness of the second amorphous carbon layer 139A may be substantially the same, and the thickness of the first graphene-containing layer 131B and the thickness of the second graphene-containing layer 139B may be substantially the same. However, embodiments of the present disclosure are not limited thereto, and if necessary, the first electrode layer 131 and the second electrode layer 139 may be realized asymmetrically. For example, the thickness of the first amorphous carbon layer 131A and the thickness of the second amorphous carbon layer 139A may be different from each other, or the thickness of the first graphene-containing layer 131B and the thickness of the second graphene-containing layer 139B may be different from each other, or both. For example, either one of the first graphene-containing layer 131B and the second graphene-containing layer 139B may be omitted, which will be described later with reference to FIGS. 3 and 4.

An example of a method for fabricating the above-described semiconductor device in FIGS. 1 and 2 will be described below.

A conductive material layer for forming a first conductive line 110 and material layers for forming a memory cell MC may be deposited over a substrate 100, and the first conductive line 110 of a line shape extending in the first direction D1 and an initial memory cell having substantially the same line shape as that of the first conductive line 110 over the first conductive line 110 may be formed by selectively etching the conductive material layer and the material layers. Subsequently, the spaces between the first conductive lines 100, and between the initial memory cells may be filled with a dielectric material, and a conductive material layer for forming a second conductive line 120 may be deposited over the initial memory cell and the dielectric material, and a line-shaped second conductive line 120 extending in the second direction D2 may be formed by selectively etching the conductive material layer. Subsequently, the initial memory cell and the dielectric material exposed by the second conductive line 120 may be selectively etched to form a pillar-shaped memory cell MC.

Meanwhile, a specific constituent element of the memory layer 135 may be diffused into both of the first amorphous carbon layer 131A and the second amorphous carbon layer 139A, or into either one of the first amorphous carbon layer 131A and the second amorphous carbon layer 139A, according to the polarity of the voltage applied to each of the first conductive line 110 and the second conductive line 120 during the operation of the memory cell MC. When the specific constituent element of the memory layer 135 is diffused into both of the first amorphous carbon layer 131A and the second amorphous carbon layer 139A, as illustrated in the embodiment of FIG. 2, the first and second graphene-containing layers 131B and 139B may be used simultaneously. Also, when the specific constituent element of the memory layer 135 is diffused into either one of the first amorphous carbon layer 131A and the second amorphous carbon layer 139A, a corresponding one of the first and second graphene-containing layers 131B and 139B may be used.

FIG. 3 is a cross-sectional view illustrating a semiconductor device in accordance with another embodiment of the present disclosure. Parts that are substantially the same as those in the above-described embodiment of the present disclosure will be denoted by the same reference numerals, and detailed description on them may be omitted for the interest of brevity.

Referring to FIG. 3, the semiconductor device in accordance with this embodiment of the present disclosure may include a substrate 100, a plurality of first conductive lines 110 formed over the substrate 100 to extend in the first direction D1, a plurality of second conductive lines 120 formed over the first conductive lines 110 to be spaced apart from the first conductive lines 110 and to extend in the second direction D2 intersecting with the first direction D1, and memory cells MC disposed between the first conductive lines 110 and the conductive lines 120 to respectively overlap at the intersection areas between the first conductive lines 110 and the second conductive lines 120. Here, each memory cell MC may include a memory layer 135, a first electrode layer 131 interposed between the memory layer 135 and the first conductive line 110, and a second electrode layer 139 interposed between the memory layer 135 and the second conductive line 120. The first electrode layer 131 may include an amorphous carbon layer. The second electrode layer 139 may include a second amorphous carbon layer 139A and a second graphene-containing layer 139B interposed between the memory layer 135 and the second amorphous carbon layer 139A.

When a positive voltage is mainly applied to the top portion of the memory cell MC, that is, to the second conductive line 120, the chalcogen element, such as selenium, of the memory layer 135 may migrate toward the second electrode layer 139, and migration toward the first electrode layer 131 may hardly occur. In this case, the second graphene-containing layer 139B may prevent and/or reduce diffusion of the selenium element into the second amorphous carbon layer 139A.

Also, a graphene-containing layer between the first electrode layer 131 and the memory layer 135 may be omitted.

Furthermore, because the first electrode layer 131 is in an amorphous state, the top surface roughness of the first electrode layer 131 may be lower than the top surface roughness of a crystal-state material. Since the memory layer 135 is disposed over the first electrode layer 131 and directly contacts the top surface of the first electrode layer 131 having a relatively low roughness, the characteristics of the memory layer 135 may be further improved according to this embodiment of the present disclosure.

FIG. 4 is a cross-sectional view illustrating a semiconductor device in accordance with another embodiment of the present disclosure.

Referring to FIG. 4, the semiconductor device in accordance with this embodiment of the present disclosure may include a substrate 100, a plurality of first conductive lines 110 formed over the substrate 100 to extend in the first direction D1, a plurality of second conductive lines 120 formed over the first conductive lines 110 to be spaced apart from the first conductive lines 110 and to extend in the second direction D2 intersecting with the first direction D1, and memory cells MC disposed between the first conductive lines 110 and the second conductive lines 120 to respectively overlap at the intersection areas between the first conductive lines 110 and the second conductive lines 120. Herein, each memory cell MC may include a memory layer 135, a first electrode layer 131 interposed between the memory layer 135 and the first conductive line 110, and a second electrode layer 139 interposed between the memory layer 135 and the second conductive line 120. The first electrode layer 131 may include a first amorphous carbon layer 131A, and a first graphene-containing layer 131B interposed between the memory layer 135 and the first amorphous carbon layer 131A. The second electrode layer 139 may include an amorphous carbon layer.

When a positive voltage is mainly applied to the bottom portion of the memory cell MC, that is, to the first conductive line 110, the chalcogen element, such as selenium, of the memory layer 135 may migrate toward the first electrode layer 131, and migration toward the second electrode layer 139 may hardly occur. In this case, the first graphene-containing layer 131B may prevent and/or reduce diffusion of the selenium element into the first amorphous carbon layer 131A. Also, a graphene-containing layer between the second electrode layer 139 and the memory layer 135 may be omitted. Accordingly, the bottom surface of the second electrode layer 139 may directly contact the memory layer 135 and have a relatively low roughness.

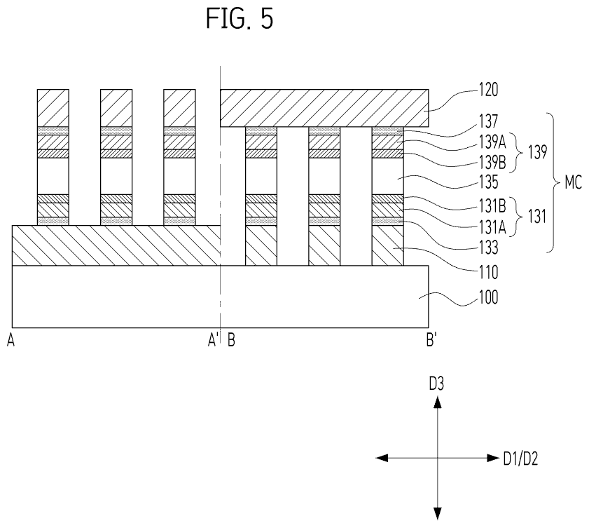

FIG. 5 is a cross-sectional view illustrating a semiconductor device in accordance with another embodiment of the present disclosure.

Referring to FIG. 5, the semiconductor device in accordance with this embodiment of the present disclosure may include a substrate 100, a plurality of first conductive lines 110 formed over the substrate 100 to extend in the first direction D1, a plurality of second conductive lines 120 formed over the first conductive lines 110 to be spaced apart from the first conductive lines 110 and to extend in the second direction D2 intersecting with the first direction D1, and memory cells MC disposed between the first conductive lines 110 and the second conductive lines 120 to respectively overlap at the intersection areas between the first conductive lines 110 and the second conductive lines 120. Here, each memory cell MC may include a memory layer 135, a first electrode layer 131 interposed between the memory layer 135 and the first conductive line 110, and a second electrode layer 139 interposed between the memory layer 135 and the second conductive line 120, a first additional electrode layer 133 interposed between the first conductive line 110 and the first electrode layer 131, and a second additional electrode layer 137 interposed between the second conductive line 120 and the second electrode layer 139. The first electrode layer 131 may include a first amorphous carbon layer 131A, and a first graphene-containing layer 131B interposed between the memory layer 135 and the first amorphous carbon layer 131A. The second electrode layer 139 may include a second amorphous carbon layer 139A, and a second graphene-containing layer 139B interposed between the memory layer 135 and the second amorphous carbon layer 139A.

Each of the first additional electrode layer 133 and the second additional electrode layer 137 may include a metal-containing material, for example, a metal, such as platinum (Pt), tungsten (W), aluminum (Al), copper (Cu), tantalum (Ta) and the like, a metal nitride such as titanium nitride (TiN), tantalum nitride (TaN) and the like, or a combination thereof. The first additional electrode layer 133 may be used to further increase the electrical conductance when it is difficult to compensate for the low electrical conductance of the first graphene-containing layer 131B only with the first amorphous carbon layer 131A. The electrical conductivity of the first additional electrode layer 133 may be higher than that of the first amorphous carbon layer 131A. The second additional electrode layer 139 may be used to further increase the electrical conductance when it is difficult to compensate for the low electrical conductance of the second graphene-containing layer 139B only with the second amorphous carbon layer 139A. The electrical conductivity of the second additional electrode layer 139 may be higher than that of the second amorphous carbon layer 139A.

Even though the first and second additional electrode layers 133 and 137 contain a metal, since the first electrode layer 131 is interposed between the first additional electrode layer 133 and the memory layer 135 and the second additional electrode layer 139 is interposed between the second additional electrode layer 137 and the memory layer 135, diffusion of the metal of the first and second additional electrode layers 133 and 137 into the memory layer 135 may be prevented and/or reduced. The thickness of the first additional electrode layer 133 may be smaller than the thickness of the first electrode layer 131, and the thickness of the second additional electrode layer 137 may be smaller than the thickness of the second electrode layer 139.

According to this embodiment of the present disclosure, the first additional electrode layer 133 and the second additional electrode layer 137 may be substantially symmetrical to each other with respect to the memory layer 135 interposed therebetween. Accordingly, the thicknesses of the first additional electrode layer 133 and the second additional electrode layer 137 may be substantially the same. However, embodiments of the present disclosure are not limited thereto, and if necessary, the first additional electrode layer 133 and the second additional electrode layer 137 may be realized asymmetrically. For example, the thickness of the first additional electrode layer 133 and the thickness of the second additional electrode layer 137 may be different from each other, or either one of the first additional electrode layer 133 and the second additional electrode layer 137 may be omitted.

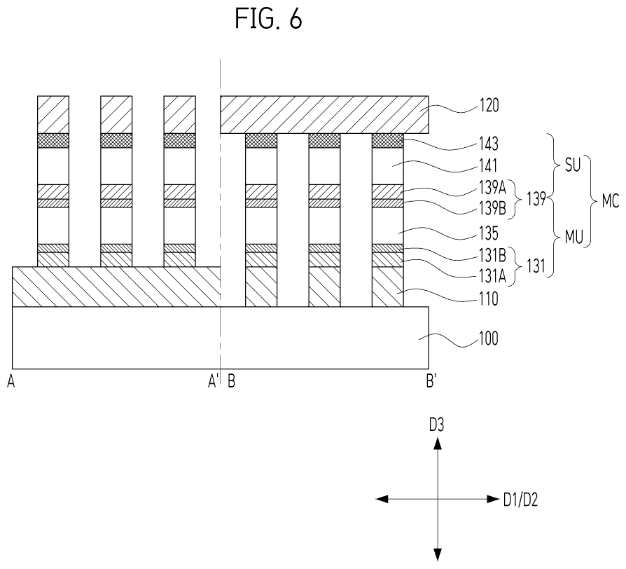

Also, according to this embodiment of the present disclosure, a case where the first and second additional electrode layers 133 and 137 are added to the semiconductor device of the embodiment shown in FIG. 2 is described, but embodiments of the present disclosure are not limited thereto. According to another embodiment of the present disclosure, at least one of the first additional electrode layer 133 or the second additional electrode layer 137 may be added to any one of the semiconductor device of the embodiment shown in FIG. 3, the semiconductor device of the embodiment shown in FIG. 4, and the semiconductor devices shown in FIGS. 6 to 8, which will be described later.

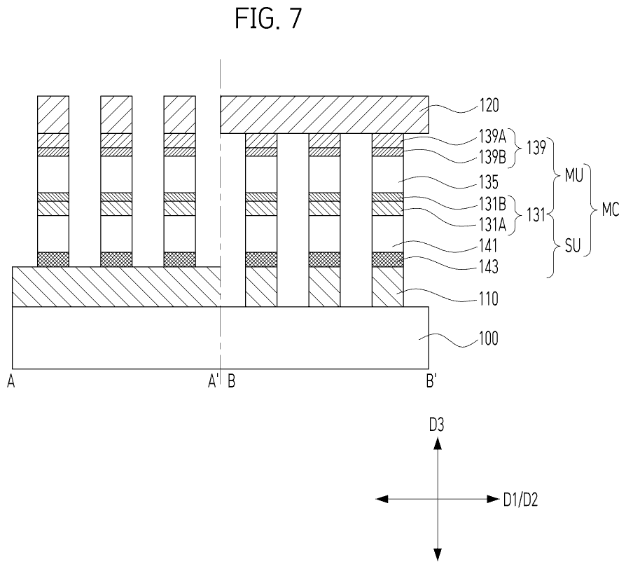

Meanwhile, the above-described embodiments of the present disclosure each corresponds to a case where the memory cell MC includes the memory layer 135 and does not include a selector layer. For example, when the memory layer 135 is a self-selecting memory layer, it may also function as a selector. Therefore, a separate selector layer may be omitted. However, when the memory layer 135 only has a data storage function and does not have a selector function, a separate selector layer may be included. These embodiments will be described with reference to FIGS. 6 and 7.

FIG. 6 is a cross-sectional view illustrating a semiconductor device in accordance with another embodiment of the present disclosure.

Referring to FIG. 6, the semiconductor device in accordance with this embodiment of the present disclosure may include a substrate 100, a plurality of first conductive lines 110 formed over the substrate 100 to extend in the first direction D1, a plurality of second conductive lines 120 formed over the first conductive lines 110 to be spaced apart from the first conductive lines 110 and to extend in the second direction D2 intersecting with the first direction D1, and memory cells MC disposed between the first conductive lines 110 and the second conductive lines 120 to respectively overlap at the intersection areas between the first conductive lines 110 and the second conductive lines 120. Here, each memory cell MC may include a memory layer 135, a selector layer 141, a first electrode layer 131 interposed between the memory layer 135 and the first conductive line 110, a second electrode layer 139 interposed between the memory layer 135 and the selector layer 141, and a third electrode layer 143 interposed between the selector layer 141 and the second conductive line 120. The memory layer 135, the first electrode layer 131, and the second electrode layer 139 may form a memory unit MU, and the selector layer 141, the second electrode layer 139, and the third electrode layer 143 may form a selector unit SU. The second electrode layer 139 may be a common electrode of the memory unit MU and the selector unit SU. According to this embodiment of the present disclosure, the selector unit SU may be disposed over the memory unit MU.

According to this embodiment of the present disclosure, the memory layer 135 may have only the data storage function and may not have the selector function. Accordingly, the memory cell MC may further include a selector layer 141 that is electrically coupled to the memory layer 135 through the second electrode layer 139.

The selector layer 141 may function to prevent or reduce current leakage that may occur between the memory cells MC sharing the first conductive line 110 or the second conductive line 120, while controlling the access to the memory layer 135. To this end, the selector layer 141 may have the threshold switching characteristics of blocking the current or holding the current to hardly flow when the level of the voltage supplied to the top and bottom portions of the selector layer 141 is lower than a predetermined threshold voltage level, and then releasing the current to flow rapidly when the level of the voltage supplied to the top and bottom portions of the selector layer 141 is equal to or higher than the threshold voltage level. In other words, the selector layer 141 may be turned on at a level equal to or higher than the threshold voltage level and turned off at a level lower than the threshold voltage level.

The selector layer 141 may include an Ovonic Threshold Switching (OTS) material such as diodes and chalcogenide-based materials, a Mixed Ionic Electronic Conducting (MIEC) material such as metal-containing chalcogenide-based materials, a Metal Insulator Transition (MIT) material such as NbO₂ and VO₂, or a tunneling dielectric material having a relatively wide band gap such as SiO₂, Al₂O₃, and the like.

Also, the selector layer 141 may include a dielectric material containing a dopant implanted by ion implantation. Here, the dielectric material may include silicon-containing dielectric materials such as silicon oxide, silicon nitride, silicon oxynitride and the like, dielectric metal oxides, dielectric metal nitrides, and combinations thereof. The dopant may serve to create trap sites that capture conductive carriers migrating in the dielectric material or to provide a passage for the captured conductive carriers to migrate again. To form the trap sites, diverse elements that create energy potentials capable of receiving conductive carriers in the dielectric material may be used as the dopant. For example, when the dielectric material includes a silicon-containing dielectric material, the dopant may include a metal whose valence is different from that of silicon, such as aluminum (Al), lanthanum (La), niobium (Nb), vanadium (V), tantalum (Ta), tungsten (W), chromium (Cr), molybdenum (Mo), gallium (Ga), boron (B), indium (In), phosphorus (P), arsenic (As), antimony (Sb), germanium (Ge), carbon (C), or a combination thereof. Also, when the dielectric material includes a dielectric metal oxide or a dielectric metal nitride, the dopant may include a metal having a different valence from that of the metal of the metal oxide or metal nitride, or silicon. For example, the selector layer 141 may include silicon dioxide (SiO₂) into which arsenic (As) is implanted by an ion implantation method. When a voltage equal to or higher than the threshold voltage is applied to the selector layer 141, the conductive carriers may migrate through the trap sites, thereby realizing an on-state in which current flows through the selector layer 141, and when the voltage applied to the selector layer 141 is decreased to a level lower than the threshold voltage, the conductive carriers may not migrate, realizing an off-state in which no current flows.

The third electrode layer 143 may be interposed between the second conductive line 120 and the selector layer 141, and may function to electrically connect them to each other while physically separating them from each other. The third electrode layer 143 may include a metal-containing material, for example, a metal such as platinum (Pt), tungsten (W), aluminum (Al), copper (Cu), tantalum (Ta) and the like, a metal nitride such as titanium nitride (TiN), tantalum nitride (TaN) and the like, or a combination thereof. Also, the third electrode layer 143 may include an amorphous carbon layer.

FIG. 7 is a cross-sectional view illustrating a semiconductor device in accordance with another embodiment of the present disclosure.

Referring to FIG. 7, the semiconductor device in accordance with this embodiment of the present disclosure may include a substrate 100, a plurality of first conductive lines 110 formed over the substrate 100 to extend in the first direction D1, a plurality of second conductive lines 120 formed over the first conductive lines 110 to be spaced apart from the first conductive lines 110 and to extend in the second direction D2 intersecting with the first direction D1, and memory cells MC disposed between the first conductive lines 110 and the second conductive lines 120 to respectively overlap at the intersection areas between the first conductive lines 110 and the second conductive lines 120. Here, each memory cell MC may include a memory layer 135, a selector layer 141, a second electrode layer 139 interposed between the memory layer 135 and the second conductive line 120, a first electrode layer 131 interposed between the memory layer 135 and the selector layer 141, and a third electrode layer 143 interposed between the selector layer 141 and the first conductive line 110. The memory layer 135, the first electrode layer 131, and the second electrode layer 139 may form a memory unit MU, and the selector layer 141, the first electrode layer 131, and the third electrode layer 143 may form the selector unit SU. The first electrode layer 131 may be a common electrode of the memory unit MU and the selector unit SU. According to this embodiment of the present disclosure, the selector unit SU may be disposed below the memory unit MU.

According to this embodiment of the present disclosure, the memory layer 135 may have only the data storage function and may not have the selector function. Accordingly, the memory cell MC may further include a selector layer 141 that is electrically connected to the memory layer 135 through the first electrode layer 131.

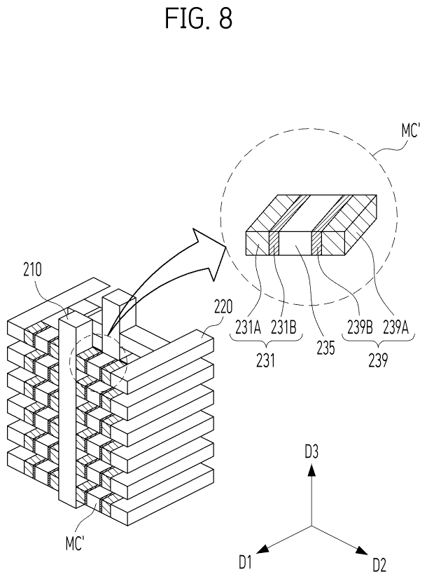

Meanwhile, according to the above-described embodiments of the present disclosure, the first conductive line 110 and the second conductive line 120 extend in respective horizontal directions while being spaced apart from each other in a vertical direction. However, the separation direction and extension directions of the first conductive line 110 and the second conductive line 120 may be changed diversely, and the memory cell MC may be disposed between the first conductive line 110 and the second conductive line 120 to overlap at the intersection area between the first conductive line 110 and the second conductive line 120. One of these embodiments will be described below with reference to FIG. 8.

FIG. 8 is a cross-sectional view illustrating a semiconductor device in accordance with another embodiment of the present disclosure.

Referring to FIG. 8, the semiconductor device in accordance with this embodiment of the present disclosure may include a plurality of first conductive lines 210 arranged in the first direction D1 and having a pillar shape extending in the third direction D3, a plurality of second conductive lines 220 formed to be spaced apart from the first conductive lines 120 in the second direction D2 and extending in the second direction D2, and memory cells MC′ disposed between the first conductive lines 210 and the second conductive lines 220 to respectively overlap at the intersection areas between the first conductive lines 210 and the second conductive lines 220. The second conductive lines 220 may be stacked in the third direction D3, and although not illustrated, a dielectric layer may be formed between the second conductive lines 220 that are adjacent to each other in the third direction D3. The third direction D3 may correspond to the vertical direction which is substantially perpendicular to the top surface of the substrate (not shown), and the first and second directions D1 and D2 may correspond to the horizontal directions which are substantially parallel to the top surface of the substrate.

Each memory cell MC′ may include a memory layer 235, a first electrode layer 231 interposed between the memory layer 235 and the first conductive line 210, and a second electrode layer 239 interposed between the memory layer 235 and the second conductive line 220. The first electrode layer 231 may include a first amorphous carbon layer 231A, and a first graphene-containing layer 231B interposed between the memory layer 235 and the first amorphous carbon layer 231A. The second electrode layer 239 may include a second amorphous carbon layer 239A, and a second graphene-containing layer 239B interposed between the memory layer 235 and the second amorphous carbon layer 239A. According to this embodiment of the present disclosure, the layers 231, 235, and 239 forming the memory cells MC′ may not be stacked in the third direction D3 but may be arranged in the second direction D2.

According to the embodiment of the present disclosure, a semiconductor device that may improve the characteristics of memory cells and a method for fabricating the semiconductor device may be provided.

While some specific embodiments of the present disclosure have been described herein, various changes and modifications may be possible.

What is claimed is:

1. A semiconductor device, comprising:
at least one memory cell,
wherein the memory cell includes:
a first electrode layer;
a second electrode layer spaced apart from the first electrode layer; and
a memory layer interposed between the first electrode layer and the second electrode layer, and
wherein the first electrode layer includes:
a first amorphous carbon layer; and
a first graphene-containing layer interposed between the memory layer and the first amorphous carbon layer.

2. The semiconductor device of claim 1, wherein the second electrode layer includes a second amorphous carbon layer.

3. The semiconductor device of claim 2, wherein the second electrode layer further includes a second graphene-containing layer interposed between the memory layer and the second amorphous carbon layer.

4. The semiconductor device of claim 3, wherein the memory layer includes a constituent element that migrates during an operation of the memory cell, and
wherein the first graphene-containing layer prevents or reduces diffusion of the constituent element into the first amorphous carbon layer, and
wherein the second graphene-containing layer prevents or reduces diffusion of the constituent element into the second amorphous carbon layer.

5. The semiconductor device of claim 3, wherein at least one of a thermal conductance or an electrical conductance of the second electrode layer is adjusted based on a thickness of the second amorphous carbon layer and a thickness of the second graphene-containing layer.

6. The semiconductor device of claim 2, wherein the second amorphous carbon layer directly contacts the memory layer.

7. The semiconductor device of claim 1, wherein the memory cell further includes a first additional electrode layer, and
wherein the first amorphous carbon layer is disposed between the first additional electrode layer and the first graphene-containing layer.

8. The semiconductor device of claim 7, wherein an electrical conductivity of the first additional electrode layer is higher than an electrical conductivity of the first amorphous carbon layer.

9. The semiconductor device of claim 7, wherein the first additional electrode layer includes a metal-containing material.

10. The semiconductor device of claim 7, wherein the memory cell further includes a second additional electrode layer, and
wherein the second amorphous carbon layer is disposed between the second additional electrode layer and the second graphene-containing layer.

11. The semiconductor device of claim 10, wherein an electrical conductivity of the second additional electrode layer is higher than an electrical conductivity of the second amorphous carbon layer.

12. The semiconductor device of claim 10, wherein the second additional electrode layer includes a metal-containing material.

13. The semiconductor device of claim 1, wherein the memory layer includes a constituent element that migrates toward the first electrode layer during an operation of the memory cell, and
wherein the first graphene-containing layer prevents or reduces diffusion of the constituent element into the first amorphous carbon layer.

14. The semiconductor device of claim 1, wherein at least one of a thermal conductance or an electrical conductance of the first electrode layer is adjusted based on a thickness of the first amorphous carbon layer and a thickness of the first graphene-containing layer.

15. The semiconductor device of claim 1, further comprising:
a plurality of first conductive lines extending in a first direction; and
a plurality of second conductive lines extending in a second direction that intersects with the first direction and spaced apart from the first conductive lines in a third direction that intersects with the first and second directions,
wherein the memory cells are arranged between the first conductive lines and the second conductive lines to respectively overlap at intersection areas between the first conductive lines and the second conductive lines.

16. The semiconductor device of claim 15, further comprising a substrate disposed below the first conductive lines, the second conductive lines, and the memory cells,
wherein the first direction and the second direction are substantially parallel to a top surface of the substrate, and the third direction is substantially perpendicular to the top surface of the substrate.

17. The semiconductor device of claim 15, further comprising a substrate disposed below the first conductive lines, the second conductive lines, and the memory cells,
wherein the first direction is substantially perpendicular to a top surface of the substrate, and the second direction and the third direction are substantially parallel to the top surface of the substrate.

18. A semiconductor device, comprising:
at least one memory cell,
wherein the memory cell includes:
a first electrode layer including a first amorphous carbon layer;
a memory layer disposed over the first electrode layer; and
a second electrode layer disposed over the memory layer and including a second amorphous carbon layer and a graphene-containing layer interposed between the second amorphous carbon layer and the memory layer, and
wherein a top surface of the first amorphous carbon layer directly contacts the memory layer.

19. The semiconductor device of claim 18, wherein the memory layer includes a constituent element that migrates toward the second electrode layer during an operation of the memory cell.

20. The semiconductor device of claim 18, wherein the memory cell further comprises an additional electrode layer, and
wherein the second amorphous carbon layer is disposed between the additional electrode layer and the graphene-containing layer.
